(19) United States
(12) Patent Application Publication
(10) Pub. No.: US 2020/0373442 A1
(43) Pub. Date: Nov. 26, 2020

(54) INTERGRATED COLOR SOLAR CELL FOR WINDOW AND MANUFACTURING METHOD THEREOF

(71) Applicants: KOOKMIN UNIVERSITY INDUSTRY ACADEMY COOPERATION FOUNDATION, Seoul (KR); KOREA INSTITUTE OF SCIENCE AND TECHNOLOGY, Seoul (KR)

(72) Inventors: Young Rag DO, Seoul (KR); Byoung Koun MIN, Seoul (KR)

(21) Appl. No.: 16/878,916

(22) Filed: May 20, 2020

(30) Foreign Application Priority Data
May 20, 2019 (KR) 10-2019-0058907

(51) Int. Cl. H01L 31/0216; H01L 31/0468; H01L 31/02; H01L 31/18; H01L 31/048

(52) U.S. Cl. CPC H01L 31/02164; H01L 31/0468; H01L 31/0481; H01L 31/186; H01L 31/02008

(57) ABSTRACT

The present disclosure relates to an integrated color solar cell for a window, and more specifically, to an integrated color solar cell for a window very suitable as a window-type as the efficiency of the solar cell is excellent, the stability of a substrate is improved, and the precise color reproduction is possible by minimizing light loss existing in the solar cell while relative harvesting efficiency and relative current density are improved without open circuit reduction by suppressing light reflection, and a manufacturing method thereof.

### CROSS-REFERENCE TO RELATED APPLICATION

This application claims priority to and the benefit of Korean Patent Application No. 2019-0058907, filed on May 20, 2019, the disclosure of which is incorporated herein by reference in its entirety.

### BACKGROUND

### 1. Field of the Invention

The present disclosure relates to an integrated color solar cell for a window, and more specifically, to an integrated color solar cell for a window very suitable as a window-type as the efficiency of the solar cell is excellent, the stability of a substrate is improved, and the precise color reproduction is possible by minimizing light loss existing in the solar cell while relative harvesting efficiency and relative current density are improved without open circuit reduction by suppressing light reflection, and a manufacturing method thereof.

### 2. Discussion of Related Art

Among various new and renewable energy technologies, a solar power generation technology which generates electricity using sunlight, which is an infinite eco-friendly energy source, is the most suitable technology geographically and technically in Korea where natural resources are scarce, and is a competitive technology. Specifically, due to increasing concern about global warming, a technology for converting solar energy into electricity has recently received more and more attention, and technologies capable of use of low-cost materials and mass production in addition to a technology for manufacturing high-efficiency solar cells are rapidly growing.

Currently, in the Korean market, bulk-type silicon (Si) solar cells lead the market and industry with high reliability and efficiency (the world's highest conversion efficiency: 25.6%), but there are limitations in application of high-cost materials and high-cost processes. Accordingly, in order to replace the high-cost bulk-type silicon solar cells, research on solar cells capable of use of low-cost materials and mass production proceeds, and inorganic solar cells or organic solar cells are suitable candidates for the above.

Recently, a solar cell plant business has been suggested as one way of maximizing a low-cost process and efficiency through research on an integrated solar cell. By dispersing electric source energy of the solar cell, it has been applied as a new attempt to cause maximization of a solar cell plant by minimizing internal communication loss as well as being a countermeasure when a problem occurs in the main source energy.

As an example, a solar cell (BIPV: Building Integrated Photovoltaic) integrated with one part of the building has been a very promising field around the world, and has shown the possibility of minimizing loss by integrating the solar cell with the building. A range of solar energy utilization can be greatly expanded not as a protection concept that can be applied to the exterior of a building, but as a tool for energy generation and it has an advantage of saving on installation and reducing costs.

In the BIPV technology, prerequisites for high efficiency, stability, costs, and color generation of the solar cell are formed, and recently, research on a solar cell which generates color as well as a high efficiency solar cell has been actively performed, and research on minimizing an efficiency reduction through glass color filters and showing the color of the solar cell has been presented. However, optical loss caused by a physical distance from the solar cell when installing the glass color filter is still difficult to solve, and research and development are necessary to solve the above.

### SUMMARY OF THE INVENTION

The present disclosure is directed to providing an integrated color solar cell for a window very suitable as a window-type as the efficiency of the solar cell is excellent, the stability of a substrate is improved, and the precise color reproduction is possible by minimizing light loss existing in the solar cell while relative harvesting efficiency and relative current density are improved without open circuit reduction by suppressing light reflection, and a manufacturing method thereof.

According to an aspect of the present disclosure, there is provided a method of manufacturing an integrated color solar cell for a window including: forming a temporary bonding layer on a solar cell; and locating a color filter, configured to reflect a portion of light and transmit the remaining light to express a predetermined color, on the temporary bonding layer and curing the temporary bonding layer to form a bonding layer.

According to one embodiment of the present disclosure, the temporary bonding layer may be formed through screen printing.

Further, one or more types of polymer selected from the group consisting of a photocurable polymer and a thermosetting polymer may be cured to form the bonding layer.

In addition, the bonding layer may include polydimethylsiloxane (PDMS).

In addition, the solar cell may be any one solar cell selected from the group consisting of a perovskite solar cell, a copper indium gallium selenide (CIGS) solar cell, a copper indium gallium selenide selenium (CIGSSe) solar cell, and a silicon solar cell.

In addition, the color filter may include a color reproduction layer formed by laminating one or more repeat units using a first layer, a second layer, and a third layer as the repeat units, a refractive index of the second layer may be different from that of the first layer, and a refractive index of the third layer may be the same as or different from that of the first layer.

In addition, the color reproduction layer may be formed by laminating the repeat units 3 to 40 times.

In addition, the refractive index of the second layer may be greater than the refractive indexes of the first layer and the third layer.

Meanwhile, according to another aspect of the present disclosure, there is provided an integrated color solar cell for a window including: a solar cell; a color filter provided on or under the solar cell and configured to reflect a portion of light and transmit the remaining light to express a predetermined color; and a bonding layer interposed between the solar cell and the color filter.

According to one embodiment of the present disclosure, the integrated color solar cell for a window may satisfy the following Condition 1.

0.85≤A/B≤1.15 Condition 1

Wherein A may be the light harvesting efficiency of the integrated color solar cell for a window in which the solar cell and the color filter are integrated through the bonding layer, and wherein B may be the light harvesting efficiency of the solar cell not including the bonding layer and the color filter.

Meanwhile, according to still another aspect of the present disclosure, there is provided a window including the above-described integrated color solar cell for a window.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a schematic view of a cross-section of an integrated color solar cell for a window according to one embodiment of the present disclosure;

FIG. 2 is a schematic view of a process of manufacturing the integrated color solar cell for a window according to one embodiment of the present disclosure;

FIG. 3(a) is a reflectance spectrum graph of blue, green, and red solar cells of the integrated color solar cell for a window according to one embodiment of the present disclosure, (b) is a color coordinate graph of a reflectance spectrum of the integrated color solar cell for a window according to one embodiment of the present disclosure, and (c) is a photograph illustrating the actual color reproduction of the integrated color solar cell for a window according to one embodiment of the present disclosure; and

FIG. 4(a to c) are graphs illustrating efficiency variations of the blue, green, and red solar cells of the integrated color solar cell for a window according to one embodiment of the present disclosure, and (d) is a graph illustrating the relative efficiency variation of each solar cell of the integrated color solar cell for a window according to one embodiment of the present disclosure.

### DETAILED DESCRIPTION OF EXEMPLARY EMBODIMENTS

Hereinafter, exemplary embodiments of the present disclosure will be described in detail to be embodied by those skilled in the art. The present disclosure may be implemented in various forms and is not limited to the following embodiments.

An integrated color solar cell for a window according to one embodiment of the present disclosure is manufactured by a process including forming a temporary bonding layer on a solar cell, and locating a color filter, configured to reflect a portion of light and transmit the remaining light to express a predetermined color, on the temporary bonding layer and curing the temporary bonding layer to form a bonding layer.

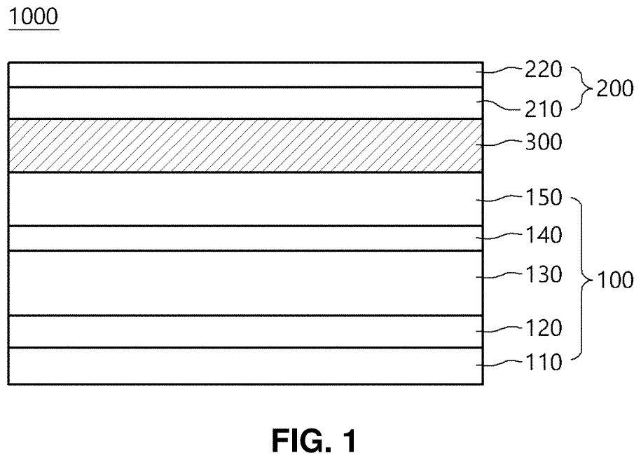

Accordingly, as shown in FIG. 1, an integrated color solar cell 1000 for a window manufactured through the method of manufacturing an integrated color solar cell for a window according to the present disclosure includes a solar cell 100, a color filter 200 which is provided on or under the solar cell 100, and reflects a portion of light and transmits the remaining light to express a predetermined color, and a bonding layer 300 interposed between the solar cell 100 and the color filter 200.

Before describing each operation for manufacturing the integrated color solar cell for a window, first, the solar cell and color filter provided in the integrated color solar cell for a window will be described.

First, the solar cell 100 will be described.

A solar cell which may be commonly used in the art may be used as the solar cell without limitation, and preferably, may be any one solar cell selected from the group consisting of a perovskite solar cell, a copper indium gallium selenide (CIGS) solar cell, a copper indium gallium selenide selenium (CIGSSe) solar cell, and a silicon solar cell, and more preferably, may be the CIGS solar cell or the CIGSSe solar cell.

As shown in FIG. 1, the solar cell 100 may be implemented in a form in which a substrate 110, a lower electrode 120, a light absorption layer 130, a buffer layer 140, and an upper electrode 150 are sequentially laminated.

First, as the substrate 110, a material commonly applicable to a thin film solar cell in the art may be used without limitation, but preferably, a glass substrate including soda-lime glass (SLG), a ceramic substrate, a metal substrate including a stainless steel substrate, a polymer substrate, and the like may be used.

Further, the lower electrode 120 is an electrode which receives electrons and holes generated by the photoelectric effect and transfers the electrons and the holes to the outside, a conductive transparent material with conductivity widely used in the art may be used as the lower electrode 120, but preferably, it may be formed by including one or more selected from the group consisting of molybdenum (Mo) and indium tin oxide (ITO), and more preferably, molybdenum to form an ohmic contact of the solar cell may be used.

In addition, the lower electrode 120 may be formed through an electron beam evaporator, physical vapor deposition (PVD), chemical vapor deposition (CVD), plasma laser deposition (PLD), dual-type thermal evaporator, sputtering, metal organic chemical vapor deposition (MOCVD), and the like, but is not limited thereto.

In addition, the light absorption layer 130 is a layer in which solar light is absorbed, a material capable of realizing the characteristics of a light absorption layer provided in the thin film solar cell may be used as the light absorption layer 130, and preferably, it may be formed of a material including at least one of copper (Cu) and silver (Ag), at least one of indium (In), gallium (Ga), aluminum (Al), zinc (Zn), and tin (Sn), and at least one of selenium (Se) and sulfur (S). More preferably, the material forming the light absorption layer 130 may be a Se based- or S based-material such as Cu(In,Ga)S2 (CIGS), Cu(In,Ga)(S,Se)2 (CIGSSe), or the like. When the thin film solar cell is composed by forming the light absorption layer, the stability and efficiency of a window-type thin film solar cell may be maintained.

In addition, any buffer layer material which may be commonly used in the art may be used in the buffer layer 140 without limitation, but preferably, a CdS thin film may be used

In addition, the upper electrode 150 is an electrode which receives the electrons and the holes generated by the photoelectric effect and transfers the electrons and the holes to the outside, and a transparent electrode formed of a conductive transparent material to be capable of realizing the characteristics of a front electrode may be used as the upper electrode 150. Preferably, transparent conductive oxides such as ITO, FTO, ZnO, ATO, PTO, AZO, and IZO or a material such as a chalcogenide may be used.

Further, the buffer layer 140 and the upper electrode 150 may be formed through an electron beam evaporator, physical vapor deposition (PVD), chemical vapor deposition (CVD), plasma laser deposition (PLD), dual-type thermal evaporator, sputtering, metal organic chemical vapor deposition (MOCVD), spin coating, and the like, but is not limited thereto.

In addition, the color filter 200 will be described.

As described above, the color filter 200 performs a function of reflecting a portion of light and transmitting the remaining light to express a predetermined color.

The color filter 200 includes a transparent substrate 210 and a color reproduction layer 220 provided on the transparent substrate 210.

A transparent substrate which may be commonly used may be used as the transparent substrate 210 without limitation, and preferably, a glass substrate may be used.

Further, the color reproduction layer 220 may be formed by lamination of at least one repeat unit formed of a first layer, a second layer, and a third layer, and in this case, a refractive index of the second layer may be different from that of the first layer, and a refractive index of the third layer may be the same as or different from that of the first layer, and preferably, the refractive index of the second layer may be greater than the refractive indexes of the first layer and the third layer.

In addition, the color reproduction layer 220 may be formed by laminating the repeat units 3 to 40 times, preferably, may be formed by laminating the repeat units 5 to 25 times, and more preferably, may be formed by laminating the repeat units 7 to 15 times. Accordingly, there is an advantage in that clear color conversion may be performed and an appropriate relative harvesting efficiency may be achieved due to a high reflectance value as well as a high transmittance value.

Meanwhile, since Korean Application Patent No. 10-1858570, which is a prior patent of the inventor of the present application, may be inserted by reference into a detailed description of the color filter of the integrated color solar cell for a window according to the present disclosure, the detailed description of the color filter will be omitted.

Hereinafter, each operation for manufacturing the integrated color solar cell for a window according to the present disclosure will be described.

First, forming the temporary bonding layer on the solar cell will be described.

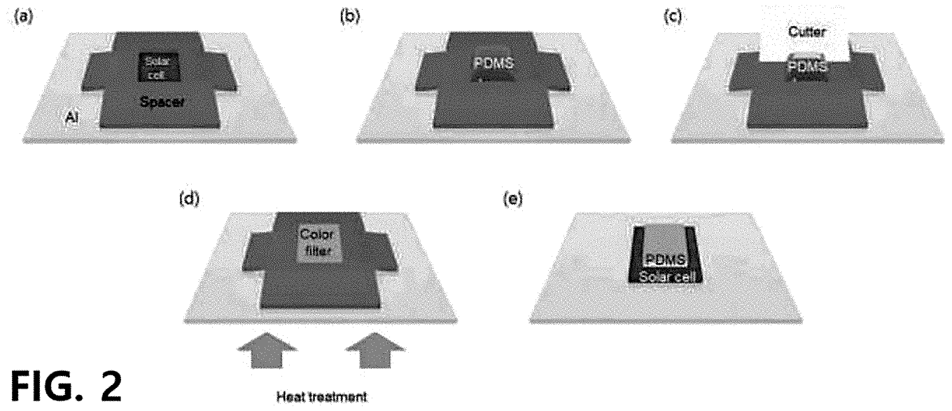

As shown in FIG. 2(a), before forming the temporary bonding layer on the solar cell, a spacer may be disposed on the solar cell to provide a target temporary bonding layer-forming region. In this case, the spacer may have a thickness greater than a thickness of a target bonding layer and smaller than or equal to 1000 μm, but is not limited thereto.

Further, in order to form the temporary bonding layer, a temporary bonding layer-forming composition may be located on the solar cell on which the spacer is disposed as shown in FIG. 2(b), and screen printing may be performed through a cutter as shown in FIG. 2(c) to form the temporary bonding layer. Since the temporary bonding layer is formed through the screen printing, effects of excellent solar cell efficiency and improved relative harvesting efficiency and relative current density without an open circuit decrease may be simultaneously realized.

Further, locating the color filter on the temporary bonding layer and curing the temporary bonding layer to form the bonding layer will be described.

As shown in FIG. 2(d), after the color filter is located on the solar cell with the temporary bonding layer, a process of curing the temporary bonding layer is performed, and the curing may be thermal curing and/or photocuring, and preferably, may be thermal curing.

Meanwhile, the temporary bonding layer-forming composition and the temporary bonding layer forming the bonding layer may include a certain polymer alone, and may also include a certain polymer and a curing agent. Further, the temporary bonding layer-forming composition and the temporary bonding layer may include one or more types of polymer selected from the group consisting of a photocurable polymer and a thermosetting polymer, and preferably, may include polydimethylsiloxane (PDMS). Since the bonding layer is formed of polydimethylsiloxane (PDMS), refractive indexes of the transparent substrate and the bonding layer provided in the above-described color filter may become similar. Accordingly, since light loss may be minimized, degradation of the efficiency of the solar cell may be further prevented.

Further, removing the spacer may be further included behind locating the color filter on the temporary bonding layer and curing the temporary bonding layer to form the bonding layer.

In this case, since the spacer may be removed through a method which may be commonly used in the art, the present disclosure is not specifically limited thereto.

The integrated color solar cell for a window according to the present disclosure manufactured through the above-described manufacturing method may satisfy the following Condition 1.

Specifically, as Condition 1, A/B may be greater than or equal to 0.85 and smaller than or equal to 1.15, and preferably, A/B may be greater than or equal to 0.95 and smaller than or equal to 1.055.

In this case, A is the light harvesting efficiency of the integrated color solar cell for a window in which the solar cell and the color filter are integrated through the bonding layer, and B is the light harvesting efficiency of the solar cell not including the bonding layer and the color filter.

Since A/B satisfies the above-described range, effects of solar cell efficiency hardly decreasing but increasing and precise color reproduction may be achieved.

According to the integrated color solar cell for a window of the present disclosure and the manufacturing method thereof, it is very suitable as a window-type as the efficiency of the solar cell is excellent, the stability of a substrate is improved, and the precise color reproduction is possible by minimizing light loss existing in the solar cell while relative harvesting efficiency and relative current density are improved without open circuit reduction by suppressing light reflection.

### EXAMPLES

The present disclosure will be more specifically described through the following examples, but the following examples do not limit the scope of the present disclosure, and should be interpreted to help understanding the present disclosure.

### Example 1

(1) Manufacture of CIGSSe Solar Cell

A solar cell device was manufactured according to the conventional structure of substrate/lower electrode/CIGSSe/CdS/i-ZnO/n-ZnO. The CIGSSe light absorption layer was manufactured using a solution-based method. The CdS buffer layer having a thickness of 60 nm was formed on the CIGSSe light absorption layer by a chemical bath deposition (CBD) method, and n-ZnO (500 nm) doped with i-ZnO (50 nm)/Al was deposited by a magnetron sputtering method.

(2) Manufacture of Color Filter

A color filter was manufactured by forming a color reproduction layer on a glass substrate which is a transparent substrate. Reflectance (R), transmittance (T), and an absorption amount (A) were simulated using a characteristic matrix method to design a BRF nano-multilayer film. In this case, a blue color filter was manufactured using an electron beam evaporator to coat an SiO₂ layer (having a thickness of 77.6 nm) and an Al₂O₃ layer (having a thickness of 70.4 nm) on the glass substrate so that the SiO₂ layer and the Al₂O₃ layer were alternately laminated in a structure of [0.5SiO₂/Al₂O₃/0.5SiO₂]¹⁸.

(3) Manufacture of Integrated Color Solar Cell for Window

A 75 μm-thick spacer having a thickness capable of providing the temporary bonding layer-forming region was formed on the manufactured solar cell, and a temporary bonding layer-forming composition including polydimethylsiloxane (PDMS) was located in the temporary bonding layer-forming region, and then, the temporary bonding layer was formed through a cutter. Further, after the manufactured color filter was located on the temporary bonding layer, and thermal curing was performed at a temperature of 80° C. for 120 minutes to cure the temporary bonding layer to form the bonding layer, the spacer was removed to manufacture the integrated color solar cell for a window.

### Example 2

In the same manner as in Example 1, a green color filter was manufactured using the electron beam evaporator to coat an SiO₂ layer (having a thickness of 90.6 nm) and an Al₂O₃ layer (having a thickness of 82.2 nm) on a glass substrate so that the SiO₂ layer and the Al₂O₃ layer were alternately laminated in a structure of [0.5SiO₂/Al₂O₃/0.5SiO₂]¹⁸ to manufacture an integrated color solar cell for a window.

### Example 3

In the same manner as in Example 1, a red color filter was manufactured using an electron beam evaporator to coat an SiO₂ layer (having a thickness of 101.4 nm) and an Al₂O₃ layer (having a thickness of 98.3 nm) on a glass substrate so that the SiO₂ layer and the Al₂O₃ layer were alternately laminated in a structure of [0.5SiO₂/Al₂O₃/0.5SiO₂]¹⁸ to manufacture an integrated color solar cell for a window.

### Comparative Example 1

In the same manner as in Example 1, a CIGSSe solar cell not including the blue color filter and the bonding layer was manufactured.

### Comparative Example 2

In the same manner as in Example 2, a CIGSSe solar cell not including the green color filter and the bonding layer was manufactured.

### Comparative Example 3

In the same manner as in Example 3, a CIGSSe solar cell not including the red color filter and the bonding layer was manufactured.

### Experimental Example 1

### Measurement of Reflectance Spectrum

For the integrated color solar cells for a window manufactured according to Examples 1 to 3, an LS-F100HS apparatus having a 100 W halogen lamp (PSI) was used to measure a reflectance spectrum.

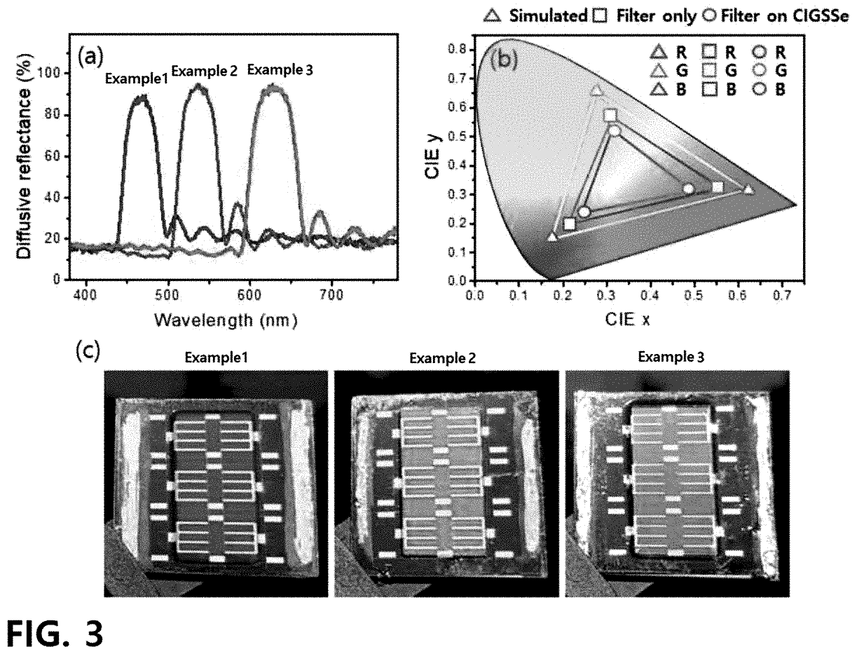

As shown in FIG. 3(a), since a half width of a reflectance band is narrow and reflectance of a center reflectance wavelength is high, it can be seen that precise color reproduction with high purity is possible.

Accordingly, as shown in FIGS. 3(b and c), it can be seen that a color of the integrated color solar cell for a window according to the present disclosure may be converted to a beautiful color. In addition, it can be seen that a width of the reflectance band is shown to be significantly narrow and thus strong color development with high purity is possible.

### Experimental Example 2

### Current Density-Voltage (J-V) Measurement and Efficiency Calculation

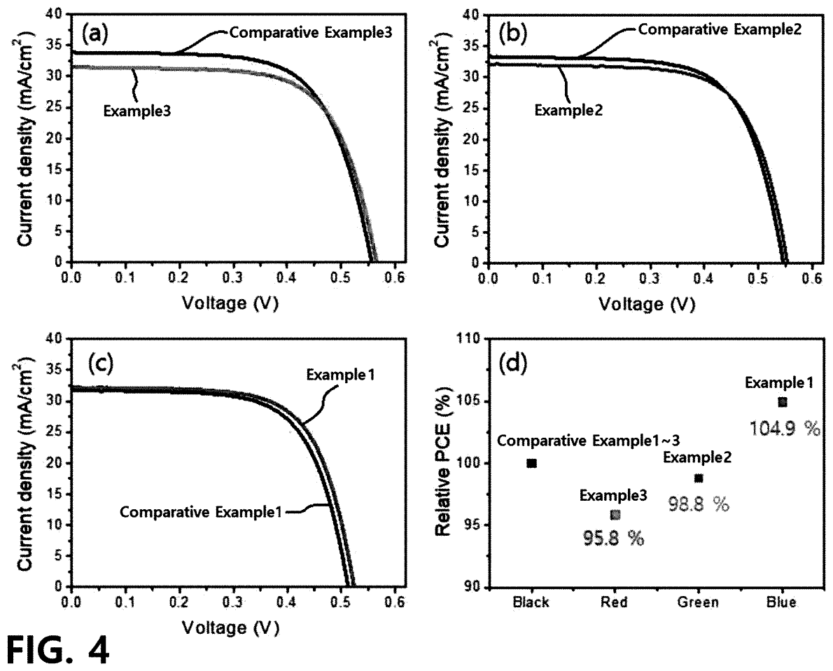

For the integrated color solar cells for a window manufactured according to Examples 1 to 3 and the CIGSSe solar cells manufactured according to Comparative Examples 1˜3, a current density-voltage (J-V) was measured using Keithley2401 provided with a 150 W xenon lamp (Newport). A light source was calibrated with a KG-5 filter, the J-V measurement was performed under sunlight, and measurement results were shown in FIG. 4(a to c).

Further, solar cell efficiency, relative efficiency (A/B) of Example 1 with respect to Comparative Example 1, relative efficiency (A/B) of Example 2 with respect to Comparative Example 2, and relative efficiency (A/B) of Example 3 with respect to Comparative Example 3 were calculated from open voltages (Voc), short circuit current densities (Jsc), and fill factors (FF) of the integrated color solar cells for a window manufactured according to Examples 1 to 3 and the CIGSSe solar cells manufactured according to Comparative Examples 1 to 3 and are shown in Tables 1 to 3.

TABLE 1

| | Voc | Jsc | FF | Eff | |
|---|---|---|---|---|---|
| Classification | (V) | (mA/cm²) | (%) | (%) | A/B |
| Example 1 | 0.53 | 32.18 | 67.3 | 11.37 | 1.049 |
| Comparative | 0.52 | 31.75 | 66.3 | 10.84 | 1.000 |
| Example 1 | | | | | |

TABLE 2

| | Voc | Jsc | FF | Eff | |
|---|---|---|---|---|---|
| Classification | (V) | (mA/cm²) | (%) | (%) | A/B |
| Example 2 | 0.55 | 32.14 | 68.1 | 12.16 | 0.988 |
| Comparative | 0.55 | 33.38 | 67.1 | 12.31 | 1.000 |
| Example 2 | | | | | |

TABLE 3

| | Voc | Jsc | FF | Eff | |
|---|---|---|---|---|---|
| Classification | (V) | (mA/cm²) | (%) | (%) | A/B |
| Example 3 | 0.57 | 31.53 | 66.7 | 11.99 | 0.958 |
| Comparative | 0.56 | 33.87 | 65.9 | 12.51 | 1.000 |
| Example 3 | | | | | |

As shown in Tables 1 to 3 and FIG. 4, it can be seen that the efficiency of the integrated color solar cells for a window manufactured according to Examples 1 to 3 of the present disclosure does not sharply decrease, but rather increases in comparison with the existing black-colored solar cells (Comparative Examples 1 to 3). That is, in the integrated color solar cell for a window according to the present disclosure, it can be seen that the efficiency of the solar cell hardly decreases, but rather increases and precise color reproduction is possible.

Accordingly, it may be confirmed that the integrated color solar cell for a window according to the present disclosure may be widely used as a building exterior wall or even an interior.

According to an integrated color solar cell for a window of the present disclosure and a manufacturing method thereof, it is very suitable as a window-type as the efficiency of the solar cell is excellent, the stability of a substrate is improved, and the precise color reproduction is possible by minimizing light loss existing in the solar cell while relative harvesting efficiency and relative current density are improved without open circuit reduction by suppressing light reflection.

Although embodiments of the present disclosure are described above, the spirit of the present disclosure is not limited to the embodiments presented in the present specification, and although those skilled in the art may provide other embodiments through the addition, change, or removal of components within the scope of the same spirit of the present disclosure, such embodiments are also included in the scope of the spirit of the present disclosure.

What is claimed is:

1. A method of manufacturing an integrated color solar cell for a window, comprising:
forming a temporary bonding layer on a solar cell; and
locating a color filter, configured to reflect a portion of light and transmit the remaining light to express a predetermined color, on the temporary bonding layer and curing the temporary bonding layer to form a bonding layer.

2. The method of claim 1, wherein the temporary bonding layer is formed through screen printing.

3. The method of claim 1, wherein one or more types of polymer selected from the group consisting of a photocurable polymer and a thermosetting polymer is cured to form the bonding layer.

4. The method of claim 1, wherein the bonding layer includes polydimethylsiloxane (PDMS).

5. The method of claim 1, wherein the solar cell is any one solar cell selected from the group consisting of a perovskite solar cell, a copper indium gallium selenide (CIGS) solar cell, a copper indium gallium selenide selenium (CIGSSe) solar cell, and a silicon solar cell.

6. The method of claim 1, wherein:
the color filter includes a color reproduction layer formed by laminating one or more repeat units using a first layer, a second layer, and a third layer as the repeat units;
a refractive index of the second layer is different from that of the first layer; and
a refractive index of the third layer is the same as or different from that of the first layer.

7. The method of claim 6, wherein the color reproduction layer is formed by laminating the repeat units 3 to 40 times.

8. The method of claim 6, wherein the refractive index of the second layer is greater than the refractive indexes of the first layer and the third layer.

9. An integrated color solar cell for a window, comprising:
a solar cell;
a color filter provided on or under the solar cell and configured to reflect a portion of light and transmit the remaining light to express a predetermined color; and
a bonding layer interposed between the solar cell and the color filter.

10. The integrated color solar cell for a window of claim 9, which satisfies the following Condition 1:
0.85≤A/B≤1.15 Condition 1
wherein A is the light harvesting efficiency of the integrated color solar cell for a window in which the solar cell and the color filter are integrated through the bonding layer, and wherein B is the light harvesting efficiency of the solar cell not including the bonding layer and the color filter.

11. A window including the integrated color solar cell for a window of claim 9.
